(19) United States
(12) Patent Application Publication
(10) Pub. No.: US 2020/0319573 A1
(43) Pub. Date: Oct. 8, 2020

(54) SEMICONDUCTOR LIGHT-EMITTING DEVICE, EXPOSURE HEAD, AND IMAGE FORMING APPARATUS

(71) Applicant: CANON KABUSHIKI KAISHA, Tokyo (JP)

(72) Inventors: Koichiro Nakanishi, Tokyo (JP); Yusuke Kamata, Tokyo (JP)

(21) Appl. No.: 16/835,480

(22) Filed: Mar. 31, 2020

(30) Foreign Application Priority Data
Apr. 2, 2019 (JP) 2019-070588

(51) Int. Cl. G03G 15/04; H01L 27/15; H01L 33/00

(52) U.S. Cl. CPC G03G 15/04036; H01L 33/0016; H01L 27/15

(57) ABSTRACT

A semiconductor light-emitting device includes a shift thyristor, a light-emitting thyristor, a transfer diode having one node connected to gates of the shift thyristor and the light-emitting thyristor, and a stacked structure including a first semiconductor layer of a first conductivity type, a second semiconductor layer of a second conductivity type different from the first conductivity type, a third semiconductor layer of the first conductivity type, and a fourth semiconductor layer of the second conductivity type. The stacked structure includes first and second mesas, the transfer diode is provided in the first mesa, and at least one of the shift thyristor and the light-emitting thyristor is provided in the second mesa. The device further includes a resistor connected to the other node of the transfer diode and including at least part of the third semiconductor layer and first and second electrodes on the third semiconductor layer.

### BACKGROUND OF THE INVENTION

### Field of the Invention

The present invention relates to a semiconductor light-emitting device, an exposure head, and an image forming apparatus.

### Description of the Related Art

As an exposure head used for forming a latent image on a photosensitive drum of an image forming apparatus, a surface light-emitting element array is used. In a typical configuration of such an exposure head, multiple plane light-emitting elements (light-emitting elements that emit light perpendicular to the primary face of a semiconductor substrate) are aligned in a certain direction, and a lens array is arranged in the same direction as the alignment direction of light-emitting elements. The light from the light-emitting elements is then captured as an image on the photosensitive drum through the lens. As a light-emitting element, an element formed of a light-emitting diode (LED) and an element formed of a light-emitting thyristor are known.

Japanese Patent Application Laid-Open No. 2012-238869 discloses a self-scanning light-emitting element array using light-emitting thyristors. In the self-scanning light-emitting element array of Japanese Patent Application Laid-Open No. 2012-238869, shift unit thyristors are coupled by a coupling diode, thereby a potential gradient is formed between gates of the shift unit thyristors, and a difference in threshold voltages of the shift unit thyristors is used to realize the self-scanning function.

In the conventional self-scanning light-emitting element array, however, influence of a parasitic capacitance coupled to a shift thyristor or a light-emitting thyristor may cause a reduction in the operation speed, an increase in inrush current, or the like in the shift thyristor and the light-emitting thyristor.

### SUMMARY OF THE INVENTION

The present invention intends to provide a semiconductor light-emitting device, an exposure head, and an image forming apparatus that are suitable for a high speed operation and reliable.

According to one aspect of the present invention, provided is a semiconductor light-emitting device including a shift thyristor, a light-emitting thyristor, and a transfer diode having one node connected to a gate of the shift thyristor and a gate of the light-emitting thyristor, wherein the semiconductor light-emitting device further includes a stacked structure including a first semiconductor layer of a first conductivity type provided over a semiconductor substrate, a second semiconductor layer of a second conductivity type, which is different from the first conductivity type, provided over the first semiconductor layer, a third semiconductor layer of the first conductivity type provided over the second semiconductor layer, and a fourth semiconductor layer of the second conductivity type provided over the third semiconductor layer, wherein the stacked structure includes a first mesa and a second mesa, wherein the transfer diode is provided in the first mesa, wherein at least one of the shift thyristor and the light-emitting thyristor is provided in the second mesa, wherein the semiconductor light-emitting device further includes a resistor connected to the other node of the transfer diode, and wherein the resistor includes at least a part of the third semiconductor layer and includes a first electrode and a second electrode provided on the third semiconductor layer.

Further features of the present invention will become apparent from the following description of exemplary embodiments with reference to the attached drawings.

### BRIEF DESCRIPTION OF THE DRAWINGS

FIG. 1A, FIG. 1B, and FIG. 1C are schematic diagrams illustrating the basic structure of a semiconductor light-emitting device according to a first embodiment of the present invention.

FIG. 2 is an equivalent circuit diagram of the semiconductor light-emitting device according to the first embodiment of the present invention.

FIG. 3A and FIG. 3B are schematic diagrams illustrating the basic structure of a semiconductor light-emitting device according to a reference example.

FIG. 4A, FIG. 4B, and FIG. 4C are schematic diagrams illustrating the basic structure of a semiconductor light-emitting device according to a second embodiment of the present invention.

FIG. 5A and FIG. 5B are schematic diagrams illustrating the basic structure of a semiconductor light-emitting device according to a third embodiment of the present invention.

FIG. 6A and FIG. 6B are schematic diagrams illustrating a configuration example of a transfer diode portion of the semiconductor light-emitting device according to the third embodiment of the present invention.

FIG. 7A and FIG. 7B are top views illustrating another configuration example of a transfer diode portion of the semiconductor light-emitting device according to the third embodiment of the present invention.

FIG. 8A and FIG. 8B are schematic cross-sectional views illustrating a configuration example of a light-emitting thyristor portion in the semiconductor light-emitting device according to the third embodiment of the present invention.

FIG. 9A and FIG. 9B are schematic cross-sectional views illustrating a configuration example of a shift thyristor portion in the semiconductor light-emitting device according to the third embodiment of the present invention.

FIG. 10 and FIG. 11 are top views illustrating an arrangement example of respective elements in the semiconductor light-emitting device according to the third embodiment of the present invention.

FIG. 12 is an equivalent circuit diagram of the semiconductor light-emitting device according to the third embodiment of the present invention.

FIG. 13A, FIG. 13B, and FIG. 13C are diagrams illustrating a transfer operation of an on-state of a shift thyristor in the semiconductor light-emitting device according to the third embodiment of the present invention.

FIG. 14 is a timing diagram illustrating a method of driving the semiconductor light-emitting device according to the third embodiment of the present invention.

FIG. 15 is a schematic diagram illustrating a configuration example of an image forming apparatus according to a fourth embodiment of the present invention.

FIG. 16A and FIG. 16B are schematic diagrams illustrating a configuration example of an exposure head of the image forming apparatus according to the fourth embodiment of the present invention.

FIG. 17A, FIG. 17B, and FIG. 17C are schematic diagrams illustrating a surface light-emitting element array chip group of the image forming apparatus according to the fourth embodiment of the present invention.

### DESCRIPTION OF THE EMBODIMENTS

Preferred embodiments of the present invention will now be described in detail in accordance with the accompanying drawings.

### First Embodiment

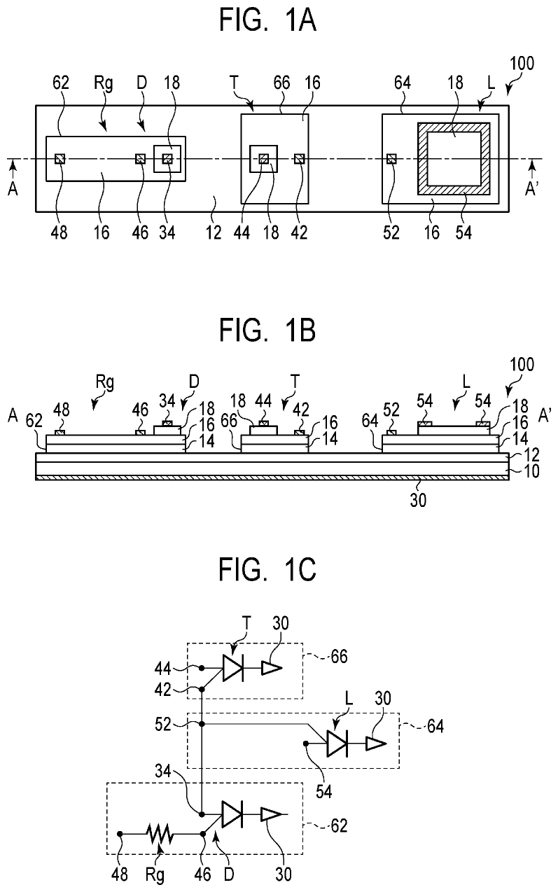

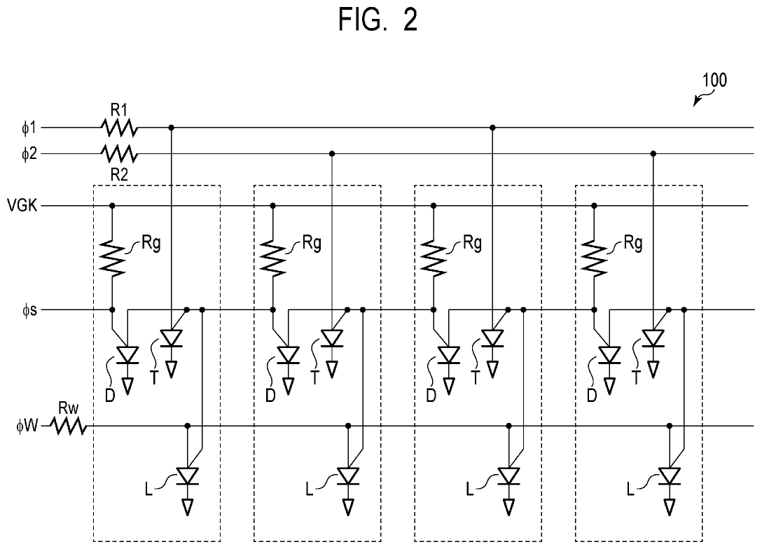

A general configuration of the semiconductor light-emitting device according to a first embodiment of the present invention will be described with reference to FIG. 1A to FIG. 2.

FIG. 1A to FIG. 1C are schematic diagrams illustrating the basic structure of the semiconductor light-emitting device according to the present embodiment. FIG. 1A is a top view, FIG. 1B is a cross-sectional view taken along the line A-A′ of FIG. 1A, and FIG. 1C is an equivalent circuit diagram. FIG. 2 is an equivalent circuit diagram of the semiconductor light-emitting device according to the present embodiment.

As illustrated in FIG. 1A to FIG. 1C, a semiconductor light-emitting device 100 according to the present embodiment includes a shift thyristor T, a transfer diode D, a light-emitting thyristor L, and a gate resistor Rg. The shift thyristor T, the transfer diode D, the light-emitting thyristor L, and the gate resistor Rg are formed by a semiconductor layer 12 of a first conductivity type, a semiconductor layer 14 of a second conductivity type, a semiconductor layer 16 of the first conductivity type, and a semiconductor layer 18 of the second conductivity type that are stacked over a semiconductor substrate 10. The first conductivity type and the second conductivity type are conductivity types that are different from each other. Note that, although a case where the first conductivity type is the n-type and the second conductivity type is the p-type will be described here as one example, the first conductivity type may the p-type and the second conductivity type may be the n-type.

The stacked structure including the semiconductor layers 12, 14, 16, and 18 is divided into a region in which the transfer diode D and the gate resistor Rg are provided, a region in which the shift thyristor T is provided, and a region in which the light-emitting thyristor L is provided. That is, the semiconductor layers 14, 16, and 18 of the region in which the transfer diode D and the gate resistor Rg are provided (transfer diode portion) form a mesa 62. Further, the semiconductor layers 14, 16, and 18 of the region in which the light-emitting thyristor L is provided (light-emitting thyristor portion) form a mesa 64. Further, the semiconductor layers 14, 16, and 18 of the region in which the shift thyristor T is provided (shift thyristor portion) form a mesa 66. The mesas 62, 64, and 66 are independent of each other. Further, the mesas 62, 64, and 66 are independent of other mesas 62, 64, and 66 (not illustrated). The semiconductor layer 12 is continuous across the transfer diode portion, the shift thyristor portion, and the light-emitting thyristor portion.

In other words, in the periphery of each of the transfer diode portion (the mesa 62), the light-emitting thyristor portion (the mesa 64), and the shift thyristor portion (the mesa 66) in plan view, the semiconductor layers 14, 16, and 18 have been removed, and the semiconductor layer 12 is exposed. Note that “expose” as used herein means that none of the semiconductor layers 14, 16, 18, and 20 is provided above a portion of interest, and another member, for example, a passivation film may be provided above the portion of interest.

The semiconductor layer 18 of the mesa 62 has been partially removed. An electrode 46 and an electrode 48 are provided apart from each other on the exposed semiconductor layer 16. An electrode 34 is provided on the semiconductor layer 18. The transfer diode D is formed of a p-n junction between the semiconductor layer 16 and the semiconductor layer 18. The electrode 34 forms the anode electrode of the transfer diode D, and the electrode 46 forms the cathode electrode of the transfer diode D. Further, the electrodes 46 and 48 are a pair of electrodes of the gate resistor Rg. That is, the semiconductor layer 16 between the electrode 46 and the electrode 48 forms the gate resistor Rg.

The semiconductor layer 18 of the mesa 64 has been partially removed. An electrode 52 is provided on the exposed semiconductor layer 16. An electrode 54 is provided on the semiconductor layer 18. The light-emitting thyristor L is formed of the p-n-p-n junction between the semiconductor layer 12, the semiconductor layer 14, the semiconductor layer 16, and the semiconductor layer 18. The electrode 54 is the anode electrode of the light-emitting thyristor L, and the electrode 52 is the gate electrode of the light-emitting thyristor L.

The semiconductor layer 18 of the mesa 66 has been partially removed. An electrode 42 is provided on the exposed semiconductor layer 16. The shift thyristor T is formed of the p-n-p-n junction between the semiconductor layer 12, the semiconductor layer 14, the semiconductor layer 16, and the semiconductor layer 18. The electrode 44 is the anode electrode of the shift thyristor T, and the electrode 42 is the gate electrode of the shift thyristor T.

An electrode 30 is provided on a face of the semiconductor substrate 10 on the opposite side to the face on which the semiconductor layers 12, 14, 16, and 18 are provided. The electrode 30 forms the cathode electrode of the light-emitting thyristor L and the shift thyristor T. When the cathode electrode is formed of the electrode 30 provided on a backside side of the semiconductor substrate 10, it is desirable that the semiconductor substrate 10 have the first conductivity type. Further, the semiconductor layer 12 may be omitted, and the semiconductor substrate 10 of the first conductivity type may be used instead of the semiconductor layer 12.

The electrodes 34, 42, and 52 are electrically connected to each other by wirings (not illustrated). The equivalent circuit diagram for such a case is as illustrated in FIG. 1C. The basic structure illustrated in FIG. 1A to FIG. 1C is arranged repeatedly, and thereby the self-scanning circuit illustrated in FIG. 2 can be formed. Note that the details or the operation of the self-scanning circuit will be described in an embodiment described later.

The composition, the thickness, and the impurity concentration of each of the semiconductor substrate 10 and the semiconductor layers 12, 14, 16, and 18 can be appropriately set so as to obtain desired thyristor characteristics in the light-emitting thyristor L and the shift thyristor T. For example, the semiconductor substrate 10 may be formed of an n-type GaAs substrate. For example, the semiconductor layer 12 may be formed of an n-type AlGaAs layer having a thickness of 600 nm, an Al composition of 25%, and a donor impurity concentration of 2×10¹⁸ cm⁻³. For example, the semiconductor layer 14 may be formed of a p-type AlGaAs layer having a thickness of 700 nm, an Al composition of 25%, and an acceptor impurity concentration of 2×10¹⁸ cm⁻³. For example, the semiconductor layer 16 may be formed of an n-type AlGaAs layer having a thickness of 350 nm, an Al composition of 15%, and a donor impurity concentration of 2×10¹⁷ cm⁻³. For example, the semiconductor layer 18 may be formed of a p-type AlGaAs layer having a thickness of 320 nm, an Al composition of 30%, and an acceptor impurity concentration of 2×10¹⁷ cm⁻³.

As described above, in the semiconductor light-emitting device according to the present embodiment, the stacked layers of the semiconductor layers 14, 16, and 18 are divided into the region in which the transfer diode D and the gate resistor Rg are provided, the region in which the shift thyristor T is provided, and the region in which the light-emitting thyristor L is provided. The reason why such a configuration is employed in the semiconductor light-emitting device of the present embodiment will be described below with reference to illustration of a semiconductor light-emitting device according to a reference example.

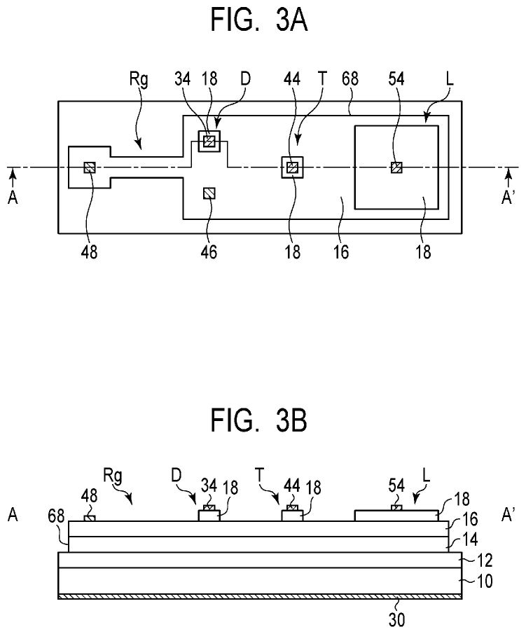

FIG. 3A and FIG. 3B are schematic diagrams illustrating the basic structure of the semiconductor light-emitting device according to the reference example. FIG. 3A is a top view, and FIG. 3B is a cross-sectional view taken along the line A-A′ of FIG. 3A. Note that the equivalent circuit diagram of the semiconductor light-emitting device according to the reference example is the same as that of FIG. 1C and FIG. 2.

As illustrated in FIG. 3A and FIG. 3B, the semiconductor light-emitting device according to the reference example has a mesa 68 in which a transfer diode portion, a shift thyristor portion, and a light-emitting thyristor portion are provided. The mesa 68 is formed of the semiconductor layers 14, 16, and 18. In a single mesa 68, each of the semiconductor layers 14, 16, and 18 is continuous across the transfer diode portion, the shift thyristor portion, and the light-emitting thyristor portion. The semiconductor layers 14, 16, and 18 forming the mesa 68 are independent of the semiconductor layers 14, 16, and 18 forming another mesa 68 (not illustrated).

The electrode 34 forming the anode of the transfer diode D, the electrode 44 forming the anode of the shift thyristor T, and the electrode 54 forming the anode of the light-emitting thyristor L are provided on the semiconductor layer 18 separated from each other, respectively. The electrode 46 serving as both the cathode of the transfer diode D and one electrode of the gate resistor Rg and the electrode 48 forming the other electrode of the gate resistor Rg are provided on the semiconductor layer 16.

The mesa 68 is structured such that the gate resistor Rg, the transfer diode D, the shift thyristor T, and the light-emitting thyristor L are electrically connected to each other. The transfer diode D is formed of the p-n junction between the anode (the semiconductor layer 18) and the gate (the semiconductor layer 16) in the thyristor structure formed of the semiconductor layers 12 to 18.

As illustrated in FIG. 3B, the mesa 68 has p-n junctions between the semiconductor layer 18 and the semiconductor layer 16, between the semiconductor layer 16 and the semiconductor layer 14, and between the semiconductor layer 14 and the semiconductor layer 12, respectively. While all of these three p-n junctions are used in the shift thyristor T and the light-emitting thyristor L, the p-n junction between the semiconductor layer 18 and the semiconductor layer 16 and the p-n junction between the semiconductor layer 16 and the semiconductor layer 14 are continuous across the whole mesa 68. Thus, the shift thyristor T and the light-emitting thyristor L will have a p-n junction capacitance in accordance with the area of the mesa 68 in plan view. In particular, when the mesa 68 integrated with the gate resistor Rg in addition to the transfer diode D is configured as illustrated in this reference example, the area of the mesa 68 in plan view, that is, the p-n junction area further increases, and therefore the p-n junction capacitances of the shift thyristor T and the light-emitting thyristor L also further increase. This may result in a reduction in the operation speed, an increase in inrush current, or the like in the shift thyristor T and the light-emitting thyristor L.

In this regard, in the semiconductor light-emitting device according to the present embodiment, the mesa 62 in which the transfer diode portion is provided, the mesa 64 in which the light-emitting thyristor portion is provided, and the mesa 66 in which the shift thyristor portion is provided are separated from each other as described above.

Therefore, according to the semiconductor light-emitting device of the present embodiment, the parasitic capacitance component coupled to the light-emitting thyristor L and the shift thyristor T can be reduced compared to the semiconductor light-emitting device of the reference example. Accordingly, it is possible to suppress a reduction in the operation speed, an increase in inrush current, or the like in the shift thyristor T and the light-emitting thyristor L and realize a reliable semiconductor light-emitting device suitable for a high speed operation.

### Second Embodiment

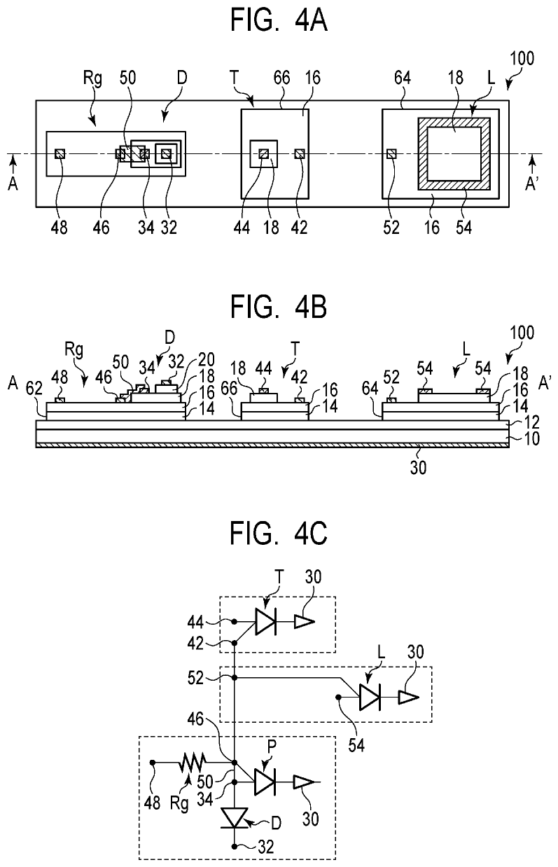

A general configuration of a semiconductor light-emitting device according to a second embodiment of the present invention will be described with reference to FIG. 4A to FIG. 4C. The same components as those of the semiconductor light-emitting device according to the first embodiment are labeled with the same references, and the description thereof will be omitted or simplified.

FIG. 4A to FIG. 4C are schematic diagrams illustrating the basic structure of the semiconductor light-emitting device according to the present embodiment. FIG. 4A is a top view, FIG. 4B is a cross-sectional view taken along the line A-A′ of FIG. 4A, and FIG. 4C is an equivalent circuit diagram.

In the first embodiment, in the semiconductor layers 12, 14, 16, and 18 forming the light-emitting thyristor L and the shift thyristor T, the p-n junction between the semiconductor layer 16 and the semiconductor layer 18 is utilized to form the transfer diode D.

In the semiconductor light-emitting device according to the present embodiment, as illustrated in FIG. 4A to FIG. 4C, a semiconductor layer 20 of the first conductivity type is further provided on the semiconductor layer 18, and the p-n junction between the semiconductor layer 18 and the semiconductor layer 20 is used to form the transfer diode D. Further, the anode and the gate of a parasitic thyristor P formed of the semiconductor layers 12, 14, 16, and 18 of the transfer diode portion are electrically connected to each other by a wiring 50. Other features are the same as those of the semiconductor light-emitting device according to the first embodiment.

The reason why such a configuration is employed in the semiconductor light-emitting device according to the present embodiment is to suppress a so-called latch-up that is a phenomenon in which the parasitic thyristor P formed in the transfer diode portion is turned on and current flows in the cathode direction. That is, in the semiconductor light-emitting device according to the first embodiment, since a part of the thyristor structure is used as the transfer diode D, the parasitic thyristor P will be turned on when a particular condition for the voltage applied to the transfer diode D is met, which may cause a malfunction.

Accordingly, in the semiconductor light-emitting device according to the present embodiment, the semiconductor layer 20 is provided, and the anode and the gate of the parasitic thyristor P is short-circuited. With such a configuration, it is possible to fix the voltage of the gate of the parasitic thyristor P to a power source voltage that is the same voltage as the anode and prevent the parasitic thyristor P from being turned on at a low voltage due to disturbance or the like. Thereby, a malfunction in the transfer diode portion can be prevented.

The composition, the thickness, and the impurity concentration of each of the semiconductor substrate 10 and the semiconductor layers 12, 14, 16, and 18 can be appropriately set so as to obtain desired thyristor characteristics in the light-emitting thyristor L and the shift thyristor T. For example, the semiconductor substrate 10 may be formed of an n-type GaAs substrate. For example, the semiconductor layer 12 may be formed of an n-type AlGaAs layer having a thickness of 600 nm, an Al composition of 25%, and a donor impurity concentration of 2×10¹⁸ cm⁻³. For example, the semiconductor layer 14 may be formed of a p-type AlGaAs layer having a thickness of 700 nm, an Al composition of 25%, and an acceptor impurity concentration of 2×10¹⁸ cm⁻³. For example, the semiconductor layer 16 may be formed of an n-type AlGaAs layer having a thickness of 350 nm, an Al composition of 15%, and a donor impurity concentration of 2×10¹⁷ cm⁻³. For example, the semiconductor layer 18 may be formed of a p-type AlGaAs layer having a thickness of 320 nm, an Al composition of 30%, and an acceptor impurity concentration of 2×10¹⁷ cm⁻³.

As described above, according to the present embodiment, it is possible to suppress a reduction in the operation speed or an increase in inrush current in the shift thyristor T and the light-emitting thyristor L, a malfunction of a parasitic thyristor, or the like and realize a reliable semiconductor light-emitting device suitable for a high speed operation.

### Third Embodiment

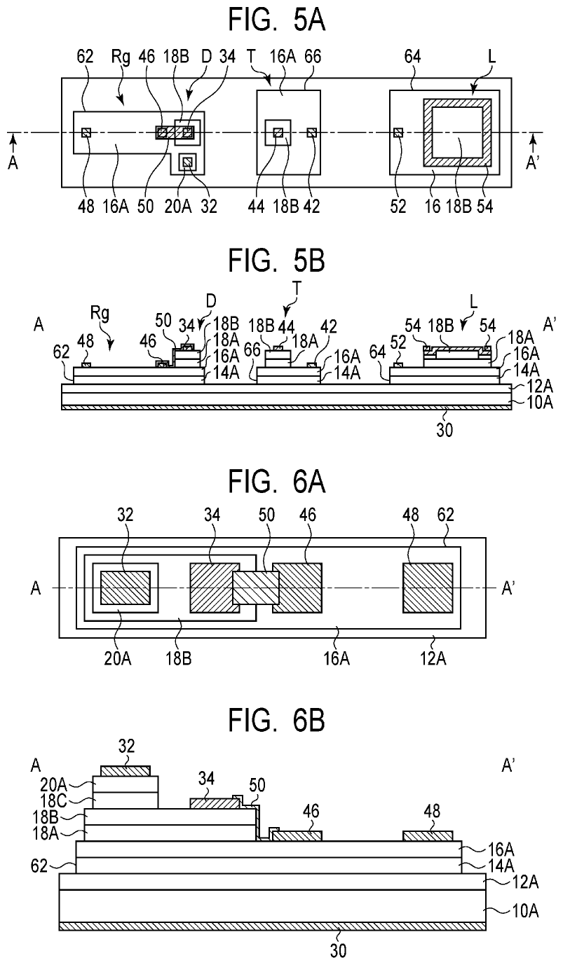

A semiconductor light-emitting device according to a third embodiment of the present invention will be described with reference to FIG. 5A to FIG. 14. The same components as those of the semiconductor light-emitting device according to the first embodiment are labeled with the same references, and the description thereof will be omitted or simplified.

First, a basic configuration of the semiconductor light-emitting device according to the present embodiment will be described with reference to FIG. 5A to FIG. 9B. The same components as those of the semiconductor light-emitting device according to the first and second embodiments are labeled with the same references, and the description thereof will be omitted or simplified.

FIG. 5A and FIG. 5B are schematic diagrams illustrating the basic structure of the semiconductor light-emitting device according to the present embodiment. FIG. 5A is a top view, and FIG. 5B is a cross-sectional view taken along the line A-A′ of FIG. 5A. Note that the equivalent circuit diagram of the semiconductor light-emitting device according to the present embodiment is the same as that illustrated in FIG. 4C.

In the present embodiment, because it is necessary to describe the relationship of impurity concentrations, the semiconductor substrate 10 and the semiconductor layers 12 to 20 will be described with exemplary specific materials for composition when the group III-V compound semiconductors are used. The components corresponding to the components illustrated in FIG. 4A to FIG. 4C are labeled with the same references, and an index A, B, or C is appended to each of the references for distinction.

Ann-type AlGaAs layer 12A, a p-type AlGaAs layer 14A, an n-type AlGaAs layer 16A, and a p-type AlGaAs layer 18A are provided on an n-type GaAs substrate 10A. A p-type AlGaAs layer 18B, a p-type AlGaAs layer 18C, and an n-type AlGaAs layer 20A are provided on the AlGaAs layer 18A.

A stacked layer of the AlGaAs layers 14A, 16A, 18A, 18B, 18C, and 20A is divided into a region in which the transfer diode D and the gate resistor Rg are provided, a region in which the shift thyristor T is provided, and a region in which the light-emitting thyristor L is provided. That is, the AlGaAs layers 14A, 16A, 18A, 18B, 18C, and 20A of the region in which the transfer diode D and the gate resistor Rg are provided (transfer diode portion) form the mesa 62. Further, the AlGaAs layers 14A, 16A, 18A, and 18B of the region in which the light-emitting thyristor L is provided (light-emitting thyristor portion) form the mesa 64. Further, the AlGaAs layers 14A, 16A, 18A, and 18B of the region in which the shift thyristor T is provided (shift thyristor portion) form the mesa 66. The mesas 62, 64, and 66 are independent of each other. Further, the mesas 62, 64, and 66 are independent of other mesas 62, 64, and 66 (not illustrated). The AlGaAs layer 12A is continuous across the transfer diode portion, the shift thyristor portion, and the light-emitting thyristor portion.

Note that the AlGaAs layers 18C and 20A are not provided in the light-emitting thyristor portion and the shift thyristor portion. The AlGaAs layers 18C and 20A of the light-emitting thyristor portion are removed after deposition or are not deposited during deposition.

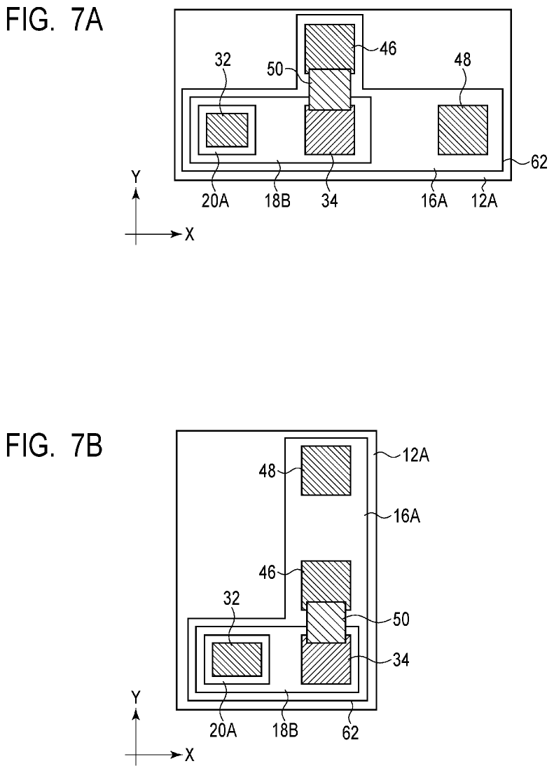

FIG. 6A and FIG. 6B illustrate only the transfer diode portion extracted from FIG. 5A and FIG. 5B. FIG. 6A is a top view, and FIG. 6B is a cross-sectional view taken along the line A-A′ of FIG. 6A.

The AlGaAs layers 14A, 16A, 18A, 18B, 18C, and 20A of the transfer diode portion form the mesa 62 including the transfer diode D, the parasitic thyristor P, and the gate resistor Rg. That is, the AlGaAs layers 14A, 16A, 18A, 18B, 18C, and 20A around the transfer diode portion have been removed, and the AlGaAs layer 12A is exposed around the transfer diode portion (the mesa 62) in plan view. Note that “expose” as used herein means that none of the AlGaAs layers 14A, 16A, 18A, 18B, 18C, and 20A is provided above a portion of interest, and another member, for example, a passivation film may be provided above the portion of interest.

The AlGaAs layers 18A, 18B, 18C, and 20A on the AlGaAs layer 16A have been partially removed. The electrode 46 forming the gate electrode of the parasitic thyristor P and one electrode of the gate resistor Rg and the electrode 48 forming the other electrode of the gate resistor Rg are provided on the exposed AlGaAs layer 16B. The AlGaAs layers 18C and 20A on the AlGaAs layer 18B have been partially removed. The electrode 34 forming the anode electrode of the transfer diode D is provided on the exposed AlGaAs layer 18B. The electrode 32 forming the cathode electrode of the transfer diode D is provided on the AlGaAs layer 20A. The electrode 30 is provided on a face of the GaAs substrate 10A on the opposite side to the face on which the AlGaAs layers 12A is provided.

In such a way, the transfer diode D is formed of the p-n junction between the p-type AlGaAs layer 18C and the n-type AlGaAs layer 20A. Further, the parasitic thyristor P is formed of the p-n-p-n junction between the p-type AlGaAs layer 18A, the n-type AlGaAs layer 16A, the p-type AlGaAs layer 14A, and the n-type AlGaAs layer 12A. Further, the gate resistor Rg is formed of the n-type AlGaAs layer 16A between the electrode 46 and the electrode 48.

In the present configuration example, to reduce the contact resistance between the p-type AlGaAs layer 18A and the electrode 34, the low resistance p-type AlGaAs layer 18B is provided as a contact layer between the p-type AlGaAs layer 18A and the electrode 34. However, if the p-n junction forming the transfer diode D is formed between the AlGaAs layer 18B and the AlGaAs layer 20A having a high impurity concentration, the reverse direction withstand voltage of the transfer diode D will decrease. Accordingly, the AlGaAs layer 18C that is of the same p-type and has a low impurity concentration is further provided between the p-type AlGaAs layer 18B and the n-type AlGaAs layer 20A.

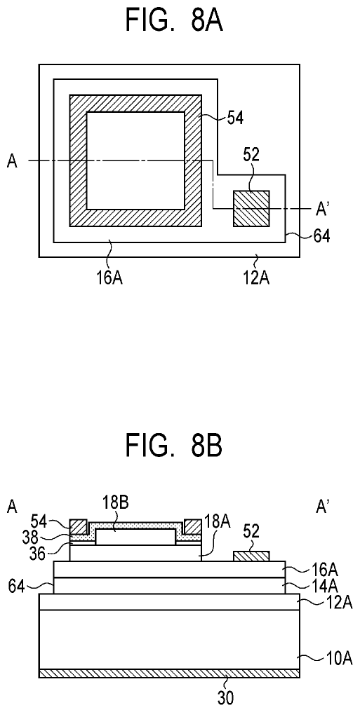

Note that, although, in FIG. 6A and FIG. 6B, the electrodes 32, 34, 46, and 48 are arranged so as to be aligned in a straight line in this order in plan view, the arrangement of the electrodes 32, 34, 46, and 48 is not limited to the example of FIG. 5A and FIG. 5B. For example, as illustrated in FIG. 7A, the electrodes 32, 34, and 48 may be arranged in this order along a first direction (the X direction in FIG. 6A and FIG. 6B), and the electrodes 34 and 46 may be arranged along a second direction (the Y direction in FIG. 6A and FIG. 6B) crossing the first direction. Alternatively, as illustrated in FIG. 7B, the electrodes 32 and 34 may be arranged along a first direction (the X direction in FIG. 6A and FIG. 6B), and the electrodes 34, 46, and 48 may be arranged in this order along a second direction (the Y direction in FIG. 6A and FIG. 6B) crossing the first direction. This arrangement corresponds to that illustrated in FIG. 5A and FIG. 5B. The arrangement of the electrodes 32, 34, 46, and 48 can be appropriately determined in accordance with the positional relationship with respect to another element (the shift thyristor T, the light-emitting thyristor L, or the like).

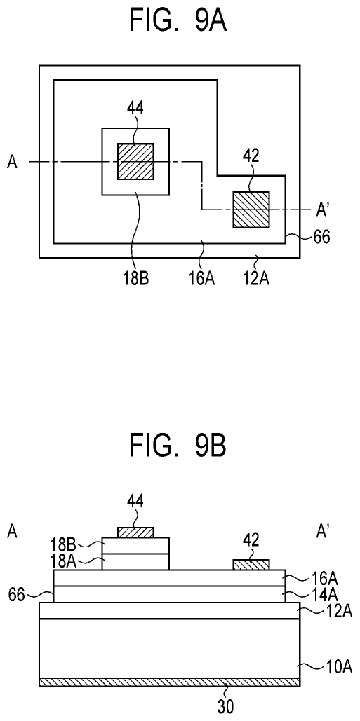

FIG. 8A and FIG. 8B illustrate only the light-emitting thyristor portion extracted from FIG. 5A and FIG. 5B. FIG. 8A is a top view, and FIG. 8B is a cross-sectional view taken along the line A-A′ of FIG. 8A.

The light-emitting thyristor portion is formed of a stacked layer including the AlGaAs layers 12A, 14A, 16A, 18A, and 18B out of the AlGaAs layers 12A, 14A, 16A, 18A, 18B, 18C, and 20A provided on the GaAs substrate 10A.

The AlGaAs layers 14A, 16A, 18A, and 18B of the light-emitting thyristor portion form the mesa 64 including the light-emitting thyristor L. That is, the AlGaAs layers 14A, 16A, 18A, and 18B around the light-emitting thyristor portion have been removed, and the AlGaAs layer 12A is exposed around the light-emitting thyristor portion (the mesa 64) in plan view. Note that “expose” as used herein means that none of the AlGaAs layers 14A, 16A, 18A, 18B, 18C, and 20A is provided above a portion of interest, and another member, for example, a passivation film may be provided above the portion of interest.

The AlGaAs layers 18A and 18B on the AlGaAs layer 16A have been partially removed. The electrode 52 forming the gate electrode of the light-emitting thyristor L is provided on the exposed AlGaAs layer 16A. The AlGaAs layer 18B on the AlGaAs layer 18A has been partially removed. An insulating layer 36 is provided on the exposed AlGaAs layer 18A. A transparent electrode 38 is provided on the AlGaAs layer 18B. The transparent electrode 38 extends on the insulating layer 36, and the electrode 54 forming the anode electrode of the light-emitting thyristor L is provided on the transparent electrode 38 in a region in which the insulating layer 36 is provided. The electrode 30 is provided on a face of the GaAs substrate 10A on the opposite side to the face on which the AlGaAs layers 12A is provided.

In such a way, the light-emitting thyristor L is formed of the p-n-p-n junction between the p-type AlGaAs layer 18A, the n-type AlGaAs layer 16A, the p-type AlGaAs layer 14A, and the n-type AlGaAs layer 12A provided in the light-emitting thyristor portion.

A light emitting current of the light-emitting thyristor L is supplied from the electrode 54 and flows to the electrode 30 via the transparent electrode 38, the AlGaAs layer 18B, the AlGaAs layer 18A, the AlGaAs layer 16A, the AlGaAs layer 14A, the AlGaAs layer 12A, and the GaAs substrate 10A. The light generated by the AlGaAs layer 16A, which is a light-emitting portion, due to the light emitting current transmits through the AlGaAs layer 18A, the AlGaAs layer 18B, and the transparent electrode 38 and is externally emitted.

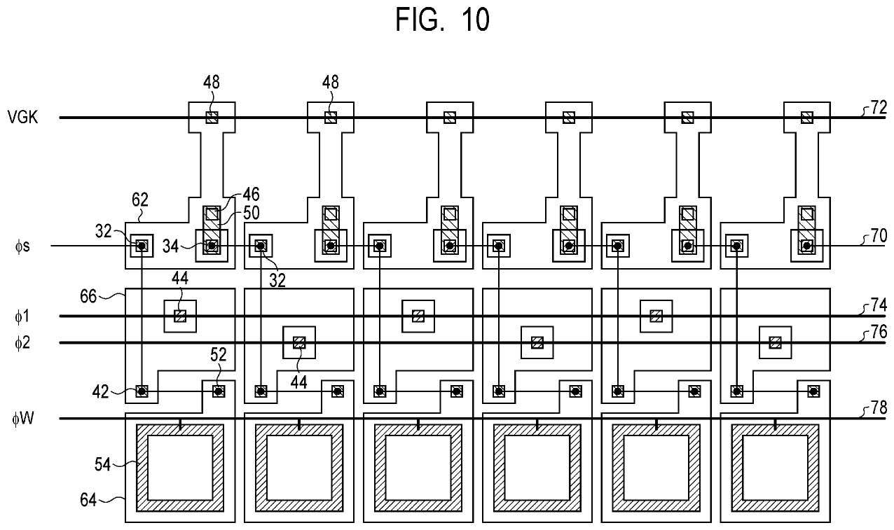

FIG. 9A and FIG. 9B illustrate only the shift thyristor portion extracted from FIG. 5A and FIG. 5B. FIG. 9A is a top view, and FIG. 9B is a cross-sectional view taken along the line A-A′ of FIG. 9A.

The shift thyristor portion is formed of a stacked layer including the AlGaAs layers 12A, 14A, 16A, 18A, and 18B out of the AlGaAs layers 12A, 14A, 16A, 18A, 18B, 18C, and 20A provided on the GaAs substrate 10A. The AlGaAs layers 18C and 20A of the shift thyristor portion are removed after deposition or are not deposited during deposition.

The AlGaAs layers 14A, 16A, 18A, and 18B of the shift thyristor portion form the mesa 66 including the shift thyristor L. That is, the AlGaAs layers 14A, 16A, 18A, and 18B around the shift thyristor portion have been removed, and the AlGaAs layer 12A is exposed around the shift thyristor portion (the mesa 66) in plan view. Note that “expose” as used herein means that none of the AlGaAs layers 14A, 16A, 18A, 18B, 18C, and 20A is provided above a portion of interest, and another member, for example, a passivation film may be provided above the portion of interest.

The AlGaAs layers 18A and 18B on the AlGaAs layer 16A have been partially removed. The electrode 42 forming the gate electrode of the shift thyristor T is provided on the exposed AlGaAs layer 16A. The electrode 44 forming the anode electrode of the shift thyristor T is provided on the AlGaAs layer 18B. The electrode 30 is provided on a face of the GaAs substrate 10A on the opposite side to the face on which the AlGaAs layers 12A is provided.

In such a way, the shift thyristor T is formed of the p-n-p-n junction between the p-type AlGaAs layer 18A, the n-type AlGaAs layer 16A, the p-type AlGaAs layer 14A, and the n-type AlGaAs layer 12A provided in the shift thyristor portion.

The structure of the shift thyristor T is the same as the structure of the light-emitting thyristor L, and the shift thyristor T emits light during the operation as a thyristor. This light emission causes image deterioration when the semiconductor light-emitting device is used as an exposure head of a copy machine, for example. It is therefore desirable that the shift thyristor portion be covered with a light-shielding member (for example, a metal film or the like) if necessary.

The composition, the thickness, and the impurity concentration of each of the AlGaAs layers 12A, 14A, 16A, and 18A are appropriately set so as to obtain desired thyristor characteristics in the light-emitting thyristor L and the shift thyristor T. The AlGaAs layers 18C and 20A are appropriately set so as to obtain desired diode characteristics as the transfer diode D.

For example, the AlGaAs layer 12A may be formed of an n-type AlGaAs layer having a thickness of 600 nm, an Al composition of 25%, and a donor impurity concentration of 2×10¹⁸ cm⁻³. The AlGaAs layer 14A may be formed of a p-type AlGaAs layer having a thickness of 700 nm, an Al composition of 25%, and an acceptor impurity concentration of 2×10¹⁸ cm⁻³. The AlGaAs layer 16A may be formed of an n-type AlGaAs layer having a thickness of 350 nm, an Al composition of 15%, and a donor impurity concentration of 2×10¹⁷ cm⁻³. The AlGaAs layer 18A may be formed of a p-type AlGaAs layer having a thickness of 320 nm, an Al composition of 30%, and an acceptor impurity concentration of 2×10¹⁷ cm⁻³.

Since the impurity concentration of the AlGaAs layer 18A is low and this makes it difficult to form an ohmic contact with a metal electrode, the AlGaAs layer 18B is provided as a contact layer. The AlGaAs layer 18B may be formed of a p-type AlGaAs layer having a thickness of 200 nm, an Al composition of 30%, and an acceptor impurity concentration of 7×10¹⁹ cm⁻³.

Further, the AlGaAs layer 18C may be formed of a p-type AlGaAs layer having a thickness of 200 nm, an Al composition of 30%, and an acceptor impurity concentration of 3×10¹⁸ cm⁻³. The AlGaAs layer 20A may be formed of an n-type AlGaAs layer having a thickness of 400 nm, an Al composition of 30%, and a donor impurity concentration of 3×10¹⁸ cm⁻³.

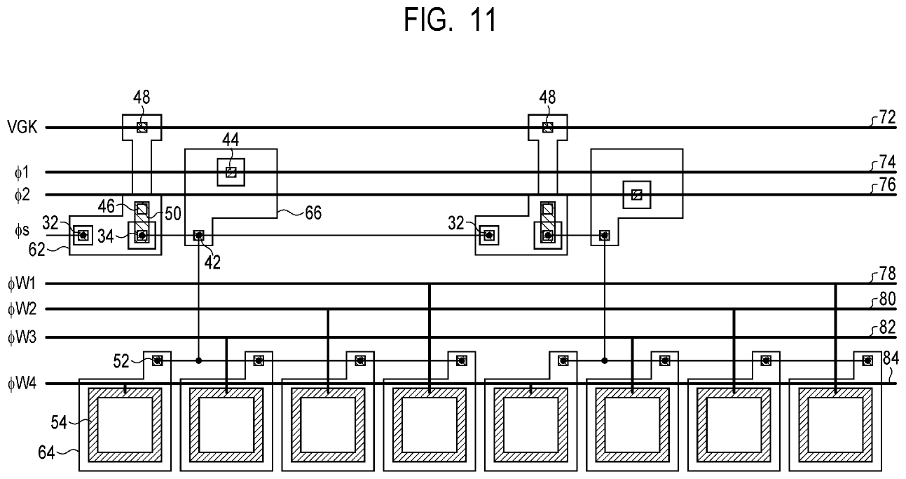

Next, the arrangement of respective elements in the semiconductor light-emitting device according to the present embodiment will be described with reference to FIG. 10 and FIG. 11.

The semiconductor light-emitting device 100 according to the present embodiment may form a self-scanning light-emitting device (SLED) using diode coupling. While the self-scanning light-emitting device may be a device using a light-emitting diode (LED) or a vertical cavity surface emitting laser (VCSEL), a light-emitting device using a thyristor has an advantage of a reduced number of wirings and is suitable for an exposure head of a copy machine or the like. In a self-scanning semiconductor light-emitting device, the shift thyristors T are coupled by the transfer diode D, thereby a potential gradient is formed between the gates of the shift thyristors T, and a self-scanning function is realized by using a threshold voltage difference between the shift thyristors T.

FIG. 10 and FIG. 11 are top views illustrating an arrangement example of respective elements when a self-scanning semiconductor light-emitting device is formed. FIG. 10 is a configuration example in which one light-emitting thyristor L is arranged to each shift thyristor T, and FIG. 11 is a configuration example in which four light-emitting thyristors L are arranged to each shift thyristor T.

A plurality of mesas 62, a plurality of mesas 64, and a plurality of mesas 66 forming a plurality of transfer diode portions, a plurality of light-emitting thyristor portions, and a plurality of shift thyristor portions of the semiconductor light-emitting device are provided apart from each other. That is, in respective mesas 62, 64, and 66, while the GaAs substrate 10 and the AlGaAs layer 12A are common, the AlGaAs layers 14A, 16A, 18A, 18B, 18C, and 20A are independent of each other as described above. For example, the AlGaAs layer 16A forming the gate resistor Rg in the mesa 62 is separate from the AlGaAs layer 16A of the mesa 64 and the AlGaAs layer 16A of the mesa 66.

A signal line forming a gate line 72 is connected to the electrode 48 provided to each of the mesas 62. A signal line forming a transfer signal line 74 is connected to the electrode 44 provided to each of the odd-numbered mesas 66. A signal line forming a transfer signal line 76 is connected to the electrode 44 provided to each of the even-numbered mesas 66. The signal lines forming lighting signal lines 78 to 84 are connected to respective electrodes 54 provided to the corresponding mesas 64.

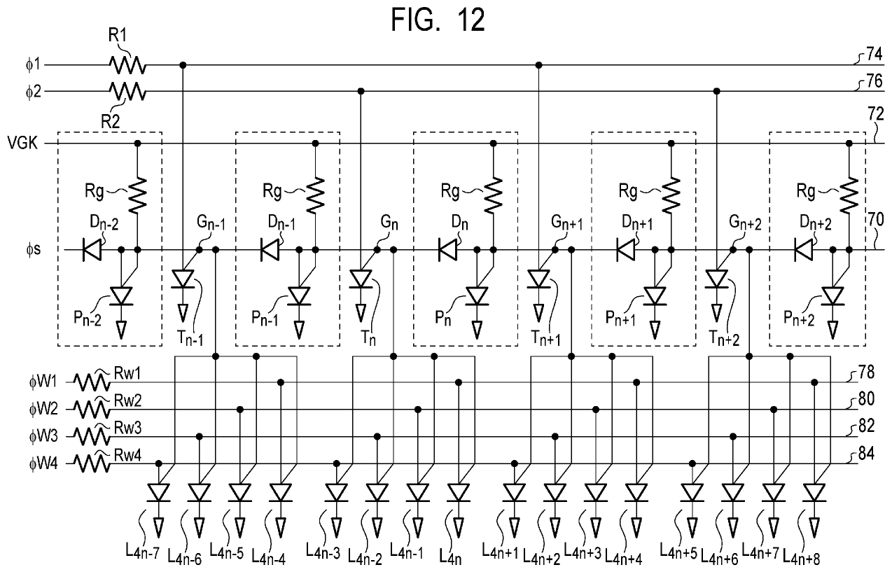

FIG. 12 is an equivalent circuit diagram of a self-scanning circuit corresponding to the configuration example of FIG. 11. In a self-scanning circuit configured in such a way, FIG. 12 illustrates four shift thyristors Tₙ₋₁ to Tₙ₊₂ as a plurality of shift thyristors T. Further, 16 light-emitting thyristors L₄ₙ₋₇ to L₄ₙ₊₈ are illustrated as a plurality of light-emitting thyristors L. Further, five transfer diodes Dₙ₋₂ to Dₙ₊₂ are illustrated as a plurality of transfer diodes D. Further, parasitic thyristors Pₙ₋₂ to Pₙ₊₂ are illustrated as the parasitic thyristors P. However, the number of shift thyristors T, the number of light-emitting thyristors L, the number of transfer diodes D, and the number of parasitic thyristors P may be selected as appropriate in accordance with the size or the like of a light-emitting device. The index “n” is an integer greater than or equal to two.

The transfer diodes Dₙ₋₂ to Dₙ₊₂ are connected in series so that the anode and the cathode of an adjacent transfer diode D are connected to each other. That is, the anode of the transfer diode Dₙ₋₂ is connected to the cathode of the transfer diode Dₙ₋₁, and the anode of the transfer diode Dₙ₋₂ is connected to the cathode of the transfer diode Dₙ. Further, the anode of the transfer diode Dₙ is connected to the cathode of the transfer diode Dₙ₊₁, and the anode of the transfer diode Dₙ₊₁ is connected to the cathode of the transfer diode Dₙ₊₂. The series-connected circuit formed of the plurality of transfer diodes Dₙ₋₂ to Dₙ₊₂ forms a start signal line 70 to which a start signal Φs is supplied. The start signal Φs is supplied from the end of the cathode side of the series-connected circuit. The anode and the gate of the parasitic thyristor P are connected to the anode of a corresponding transfer diode D, and the cathode of the parasitic thyristor P is connected to a reference voltage.

Each of the connection nodes between adjacent transfer diodes D is connected via a gate resistor Rg to a gate line 72 to which a power source voltage VGK is supplied. Further, the gate of one shift thyristor T and the gates of four light-emitting thyristors L are connected to each of the connection nodes between adjacent transfer diodes D. That is, the gate of the shift thyristor Tₙ₋₁ and the gates of the light-emitting thyristors L₄ₙ₋₇ to L₄ₙ₋₄ are connected to the connection node between the transfer diode Dₙ₋₂ and the transfer diode Dₙ₋₁ (a common gate Gₙ₋₁). The gate of the shift thyristor Tₙ and the gates of the light-emitting thyristors L₄ₙ₋₃ to L₄ₙ are connected to the connection node between the transfer diode Dₙ₋₁ and the transfer diode Dₙ (a common gate Gₙ). The gate of the shift thyristor Tₙ₊₁ and the gates of the light-emitting thyristors L₄ₙ₊₁ to L₄ₙ₊₄ are connected to the connection node between the transfer diode Dₙ and the transfer diode Dₙ₊₁ (a common gate Gₙ₊₁). The gate of the shift thyristor Tₙ₊₂ and the gates of the light-emitting thyristors L₄ₙ₊₅ to L₄ₙ₊₈ are connected to the connection node between the transfer diode Dₙ₊₁ and the transfer diode Dₙ₊₂ (a common gate Gₙ₊₂).

The anodes of odd-numbered shift thyristors T (for example, the shift thyristors Tₙ₋₁, Tₙ₊₁) are connected to a transfer signal line 74 to which a transfer signal Φ1 is supplied via an input resistor R1. The anodes of even-numbered shift thyristors T (for example, the shift thyristors Tₙ, Tₙ₊₂) are connected to a transfer signal line 76 to which a transfer signal Φ2 is supplied via an input resistor R2.

The anode of the light-emitting thyristor L is connected to a predetermined lighting signal line to which a lighting signal ΦW is supplied via a resistor Rw. That is, the anodes of the light-emitting thyristors L₄ₙ₋₇, L₄ₙ₋₃, L₄ₙ₊₁, and L₄ₙ₊₅ are connected to a lighting signal line 84 to which a lighting signal ΦW4 is supplied via a resistor Rw4. The anodes of the light-emitting thyristors L₄ₙ₋₆, L₄ₙ₋₂, L₄ₙ₊₂, and L₄ₙ₊₆ are connected to a lighting signal line 82 to which a lighting signal ΦW3 is supplied via a resistor Rw3. The anodes of the light-emitting thyristors L₄ₙ₋₅, L₄ₙ₋₁, L₄ₙ₊₃, and L₄ₙ₊₇ are connected to a lighting signal line 80 to which a lighting signal ΦW2 is supplied via a resistor Rw2. The anodes of the light-emitting thyristors L₄ₙ₋₄, L₄ₙ, L₄ₙ₊₄, and L₄ₙ₊₈ are connected to a lighting signal line 78 to which a lighting signal ΦW1 is supplied via a resistor Rw1.

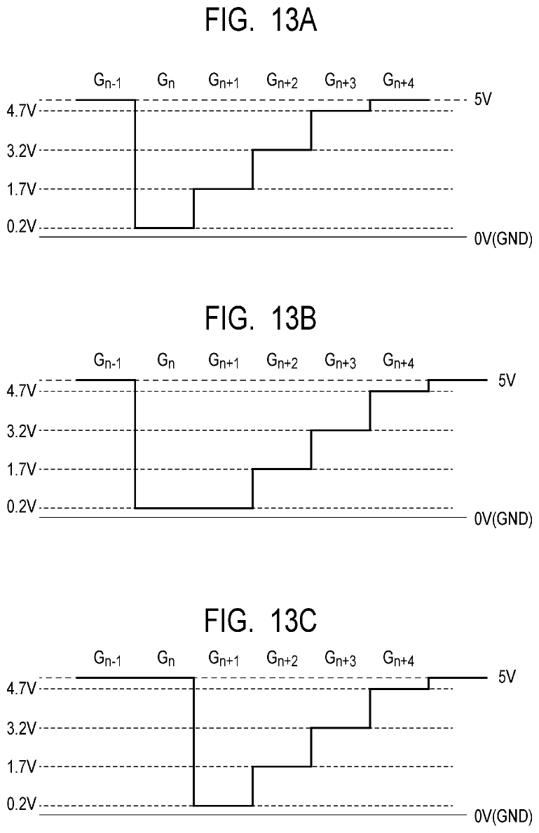

Next, a transfer operation in an on-state of the shift thyristor T in the semiconductor light-emitting device 100 according to the present embodiment will be described with reference to FIG. 12 to FIG. 13C. In this example, the power source voltage VGK supplied to the gate line 72 is 5 V, and the transfer signals Φ1 and Φ2 supplied to the transfer signal lines 74 and 76 are at either 0 V or 5 V.

FIG. 13A to FIG. 13C are diagrams illustrating the transfer operation in the on-state of shift thyristors in the semiconductor light-emitting device according to the present embodiment.

FIG. 13A illustrates a distribution of the potentials of the common gates Gₙ₋₁ to Gₙ₊₄ when the transfer signal Φ1 is at 0 V, the transfer signal Φ2 is at 5V, and the shift thyristor Tₙ is in the on-state. Note that the common gates Gₙ₊₃ and Gₙ₊₄ are common gates that are on the post-stage of the common gate Gₙ₊₂ and are not illustrated in FIG. 12.

When the shift thyristor Tₙ is in the on-state, the potential of the common gate Gₙ connected to the gate of the shift thyristor Tₙ and the gates of the light-emitting thyristors L₄ₙ₋₃ to L₄ₙ decreases to around 0.2 V. A potential difference that is substantially the same as a diffusion potential of the transfer diode Dₙ that connects the common gate Gₙ to the common gate Gₙ₊₁ occurs between the common gate Gₙ and the common gate Gₙ₊₁. In the present embodiment, the diffusion potential of the transfer diode Dₙ is around 1.5 V, and the potential of the common gate Gₙ₊₁ is 1.7 V that is an addition of 0.2 V, which is the potential of the common gate Gₙ, and 1.5V, which is the diffusion potential of the transfer diode Dₙ. Similarly, the potential of the common gate Gₙ₊₂ is 3.2 V, and the potential of the common gate Gₙ₊₃ (not illustrated) is 4.7 V.

Here, since the upper limit voltage of the common gate G is the power source voltage VGK, the potential of the common gate Gₙ₊₄ and the post-stage thereof is 5 V that is the value of the power source voltage VGK. Further, since the transfer diode D between the common gate Gₙ and the common gate Gₙ₋₁ is reverse-biased, the power source voltage VGK is directly supplied to the common gate Gₙ₋₁. The same applies for the common gate G on the pre-stage of the common gate Gₙ₋₁. That is, the potential of the common gate Gₙ₋₁ or the like on the pre-stage of the common gate Gₙ is 5 V that is the value of the power source voltage VGK. In such a way, the potential gradient as illustrated in FIG. 13A is formed in the common gates Gₙ to Gₙ₊₃.

A voltage (threshold voltage) required to turn on the shift thyristor T is substantially the same as a voltage that is an addition of the gate potential and the diffusion potential. When the shift thyristor Tₙ is turned on, the shift thyristor having the lowest gate potential in other shift thyristors T connected to the transfer signal line 76 to which the transfer signal Φ2 is supplied is the shift thyristor Tₙ₊₂. The potential of the common gate Gₙ₊₂ corresponding to the shift thyristor Tₙ₊₂ is 3.2 V as described above, and the threshold voltage of the shift thyristor Tₙ₊₂ is 4.7 V.

However, because the shift thyristor Tₙ is in the on-state, the potential of the transfer signal line 76 to which the transfer signal Φ2 is supplied has decreased to the voltage corresponding to the diffusion potential (around 1.5 V). Thus, the potential of the transfer signal line 76 to which the transfer signal Φ2 is supplied is lower than the threshold voltage of the shift thyristor Tₙ₊₂, and the shift thyristor Tₙ₊₂ is unable to be turned on. All the other shift thyristors T connected to the same transfer signal line 76 have higher threshold voltages than the shift thyristor Tₙ₊₂ and thus are unable to be turned on as with the shift thyristor Tₙ₊₂. As a result, only the shift thyristor Tₙ can be maintained in the on-state.

FIG. 13B illustrates a distribution of the potentials of the common gates Gₙ₋₁ to Gₙ₊₄ when the transfer signal Φ1 is changed to 5 V from the state of FIG. 13A.

When the shift thyristor T connected to the transfer signal line 74 to which the transfer signal Φ1 is supplied is focused on, the threshold voltage of the shift thyristor Tₙ₊₁ in a state of the lowest threshold voltage is 3.2 V. The threshold voltage of the shift thyristor Tₙ₊₃ in a state of the next lowest threshold voltage is 6.2 V. Therefore, when the transfer signal Φ1 is changed from 0 V to 5 V in this state, only the shift thyristor Tₙ₊₁ can be turned on out of the shift thyristors T connected to the transfer signal line 74 to which the transfer signal Φ1 is supplied. In this state, the shift thyristor Tₙ and the shift thyristor Tₙ₊₁ are in the on-state, and the gate potentials of the shift thyristors T on the right side of the shift thyristor Tₙ₊₁ decrease each by the diffusion potential. However, the power source voltage VGK is 5 V, and the gate potential is limited by the power source voltage VGK. Therefore, the gate potential is 5 V in the shift thyristors T on the right side of the shift thyristor Tₙ₊₅.

FIG. 13C illustrates a distribution of the potentials of the common gates Gₙ₋₁ to Gₙ₊₄ when the transfer signal Φ2 is changed to 0 V from the state of FIG. 13B.

When the transfer signal Φ2 is changed from 5 V to 0 V, the shift thyristor Tₙ is turned off. Thereby, the potential of the common gate Gₙ increases to the power source voltage VGK.

In such a way, transfer of the on-state from the shift thyristor Tₙ to the shift thyristor Tₙ₊₁ is completed.

Note that, while the parasitic thyristor P is connected to the anode of the transfer diode D, the anode and the gate of the parasitic thyristor P is connected to the power supply voltage VGK via the gate resistor Rg. Thus, since the gate of the parasitic thyristor P is maintained at the same potential as the anode even if disturbance or the like is applied to the anode of the parasitic thyristor P, a so-called latch-up that is a phenomenon in which the parasitic thyristor P is turned on and current flows in the cathode direction can be prevented. Therefore, the parasitic thyristor P would not affect the transfer operation in the on-state of the shift thyristor T.

Next, a light-emitting operation of the light-emitting thyristor L in the semiconductor light-emitting device according to the present embodiment will be described with reference to FIG. 12 to FIG. 14. In this example, the power supply voltage VGK supplied to the gate line 72 is 5 V, and voltages of the transfer signals Φ1 and Φ2 supplied to the transfer signal lines 74 and 76 and the lighting signals ΦW1 to ΦW4 supplied to the lighting signal lines 78 to 84 are either 0 V or 5 V.

When the shift thyristor Tₙ is in the on-state, the potential of the common gate Gₙ is around 0.2 V as described above. Therefore, the threshold voltage of the light-emitting thyristors L₄ₙ₋₃ to L₄ₙ connected to the common gate Gₙ is 1.7 V. That is, if the lighting signals ΦW1 to ΦW4 having a voltage of 1.7 V or higher are supplied, the light-emitting thyristors L₄ₙ₋₃ to L₄ₙ can emit light. Here, the lighting signals ΦW1, ΦW2, ΦW3, and ΦW4 correspond to the light-emitting thyristors L₄ₙ₋₃, L₄ₙ₋₂, L₄ₙ₋₁, and L₄ₙ, respectively. Therefore, the light-emitting thyristors L₄ₙ₋₃, L₄ₙ₋₂, L₄ₙ₋₁, and L₄ₙ can be caused to emit light by any combination in accordance with a combination of the lighting signals ΦW1, ΦW2, ΦW3, and ΦW4.

When the potential of the common gate Gₙ is 0.2 V, the potential of the adjacent common gate Gₙ₊₁ is 1.7 V, and the threshold voltage of the light-emitting thyristors L₄ₙ₊₁ to L₄ₙ₊₄ connected to the common gate Gₙ₊₁ is 3.2 V. Since the lighting signals ΦW1 to ΦW4 are at 5 V, it appears that the light-emitting thyristors L₄ₙ₊₁ to L₄ₙ₊₄ emit light at the same time as lighting drive of the light-emitting thyristors L₄ₙ₋₃ to L₄ₙ.

However, since the threshold voltages of the light-emitting thyristors L₄ₙ₋₃ to L₄ₙ are lower than the threshold voltages of the light-emitting thyristors L₄ₙ₊₁ to L₄ₙ₊₄, the light-emitting thyristors L₄ₙ₋₃ to L₄ₙ are turned on earlier than the light-emitting thyristors L₄ₙ₊₁ to L₄ₙ₊₄. Once the light-emitting thyristors L₄ₙ₊₁ to L₄ₙ₊₄ are turned on, the potential of the lighting signal lines 78 to 84 connected to the turned-on light-emitting thyristors L₄ₙ₊₁ to L₄ₙ₊₄ decreases to 1.5 V corresponding to the diffusion potential. As a result, the potential of the lighting signal lines 78 to 84 of interest becomes lower than the threshold voltage of the light-emitting thyristors L₄ₙ₊₁ to L₄ₙ₊₄, and the light-emitting thyristors L₄ₙ₊₁ to L₄ₙ₊₄ are not turned on.

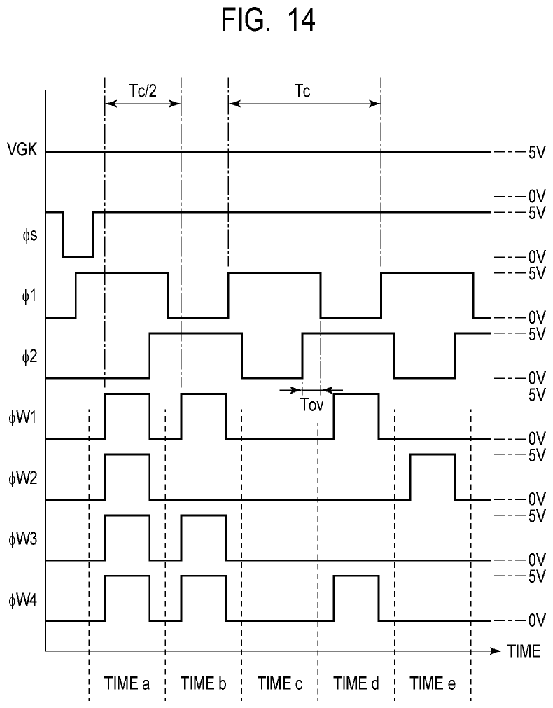

FIG. 14 is a timing diagram illustrating one example of a method of driving the semiconductor light-emitting device according to the present embodiment. FIG. 14 illustrates the power supply voltage VGK, the start signal Φs, the transfer signals Φ1 and Φ2, and the lighting signals ΦW1, ΦW2, ΦW3, and ΦW4. The transfer signal Φ1 is a clock signal used for the odd-numbered shift thyristors T, and the transfer signal Φ2 is a clock signal used for the even-numbered shift thyristors T.

First, the start signal Φs is changed from 5 V to 0 V. Thereby, the potential of the common gate G connected to the gate of the shift thyristor T that is closest to the input side of the start signal Φs (for example, the common gate Gₙ₋₁) decreases from 5 V to 1.7 V, and the threshold voltage of the shift thyristor Tₙ₋₁ is 3.2 V. Thereby, the shift thyristor Tₙ₋₁ is ready to be turned on by the transfer signal Φ1.

Next, the transfer signal Φ1 is changed from 0 V to 5 V to turn on the shift thyristor Tₙ₋₁. Further, slightly after the shift thyristor Tₙ₋₁ is turned on, the start signal Φs is changed from 0 V to 5 V. The start signal Φs remains at 5 V until the start timing of the next lighting operation.

The transfer signal Φ1 is the clock signal used for the odd-numbered shift thyristors T and has periodic pulses rising from 0 V to 5 V in a cycle Tc. The transfer signal Φ2 is a clock signal used for the even-numbered shift thyristors T and has periodic pulses rising from 0 V to 5 V at the same cycle Tc as the transfer signal Φ1. The transfer signal Φ1 and the transfer signal Φ2 are signals of approximately opposite phases but are configured to have a period Tov in which the on-states (periods of 5V) of both the transfer signals are overlapped after a rising edge and before a falling edge of each pulse.

The lighting signals ΦW1, ΦW2, ΦW3, and ΦW4 are transmitted in a half the cycle of the transfer signals Φ1 and Φ2 (Tc/2). If the lighting signal ΦW of 5 V is applied when the shift thyristor T is in the on-state, the light-emitting thyristor L corresponding to the lighting signal ΦW that has transitioned to 5V emits light.

For example, at time a, out of four light-emitting thyristors L connected to the same shift thyristor T (for example, the shift thyristor Tₙ₋₁), four light-emitting thyristors L corresponding to the lighting signals ΦW1, ΦW2, ΦW3, and ΦW4 emit light at the same time. Further, at time b, out of four light-emitting thyristors L connected to the same shift thyristor T (for example, the shift thyristor Tₙ), three light-emitting thyristors L corresponding to the lighting signals ΦW1, ΦW3, and ΦW4 emit light at the same time. Further, at time c, all the lighting signals ΦW1, ΦW2, ΦW3, and ΦW4 are at 0 V, and all the light-emitting thyristors L are thus in the turn-off state. Further, at time d, out of four light-emitting thyristors L connected to the same shift thyristor T (for example, the shift thyristor Tₙ₊₂ (not illustrated)), two light-emitting thyristors L corresponding to the lighting signals ΦW1 and ΦW4 emit light at the same time. Further, at time e, out of four light-emitting thyristors L connected to the same shift thyristor T (for example, the shift thyristor Tₙ₊₃), only the light-emitting thyristor L corresponding to the lighting signal ΦW2 emits light.

As described above, according to the present embodiment, it is possible to suppress a reduction in the operation speed or an increase in inrush current of the shift thyristor T and the light-emitting thyristor L, a malfunction of the parasitic thyristor P, or the like and realize a reliable semiconductor light-emitting device suitable for a high speed operation.

### Fourth Embodiment

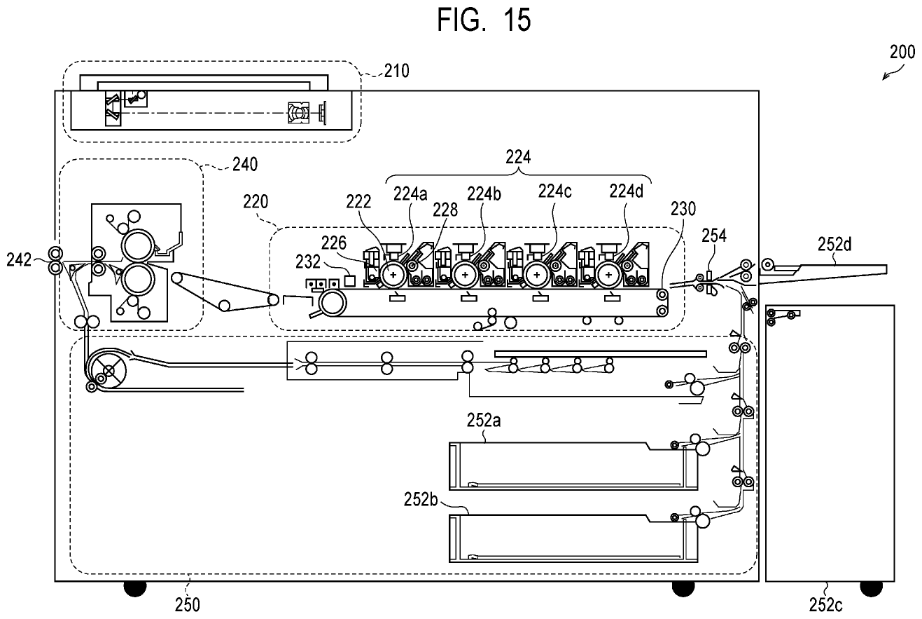

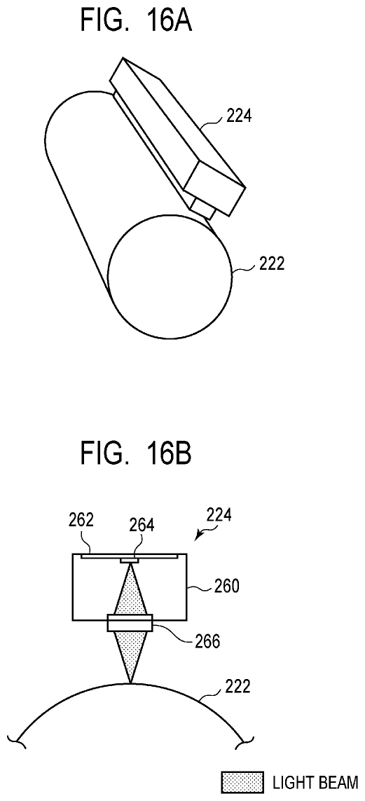

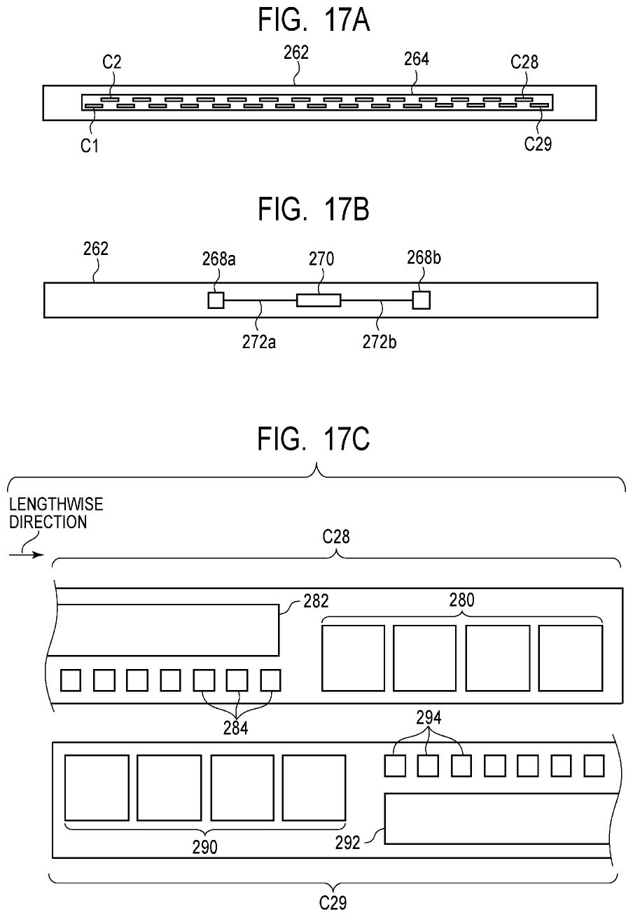

An image forming apparatus according to a fourth embodiment of the present invention will be described with reference to FIG. 15 to FIG. 17C. The same components as those of the semiconductor light-emitting device according to the first to third embodiments are labeled with the same references, and the description thereof will be omitted or simplified. FIG. 15 is a schematic diagram illustrating a configuration example of the image forming apparatus according to the present embodiment. FIG. 16A and FIG. 16B are schematic diagrams illustrating a configuration example of an exposure head of the image forming apparatus according to the present embodiment. FIG. 17A to FIG. 17C are schematic diagrams illustrating a surface light-emitting element array chip group of the image forming apparatus according to the present embodiment.

The semiconductor light-emitting device 100 described as each of the first to third embodiments is applicable to image forming apparatus such as an image scanner, a copy machine, a fax machine, or the like, for example. In the present embodiment, an electrophotographic image forming apparatus will be described as one example of an electronic apparatus using the semiconductor light-emitting device 100 of each of the first to third embodiments.

As illustrated in FIG. 15, an image forming apparatus 200 according to the present embodiment has a scanner unit 210, an imaging unit 220, a fixing unit 240, a sheet feed/transport unit 250, and an image forming control unit (not illustrated) that controls these components.

The scanner unit 210 emits lighting to a document placed on a document stage to optically read an image of the document and converts the image into an electrical signal to create image data.

The imaging unit 220 has a plurality of development units that perform development by using an electrophotographic process. Each development unit has a photosensitive drum 222, an exposure head 224, a charger 226, and a developer 228. The development unit may be a process cartridge accommodating a configuration used for development of a toner image. In such a case, it is preferable that the process cartridge be removable with respect to the main body of the image forming apparatus.

The photosensitive drum 222 is an image carrier on which an electrostatic latent image is formed. The photosensitive drum 222 is rotary-driven and charged by the charger 226.

The exposure head 224 irradiates the photosensitive drum 222 with a light in accordance with the image data and forms an electrostatic latent image on the photosensitive drum 222.

The developer 228 supplies a toner (development agent) to an electrostatic latent image formed on the photosensitive drum 222 to perform development. The toner is accommodated in an accommodation unit. It is preferable that the accommodation unit accommodating a toner be included in the development unit. The developed toner image (development agent image) is transferred on a recording medium such as a sheet transported on a transfer belt 230.

The image forming apparatus of the present embodiment has four development units (development stations) that perform development by using a series of electrophotographic processes and forms a desired image by transferring a toner image from each development unit. The four development units have respective toners of different colors. Specifically, four development units aligned in the order of cyan (C), magenta (M), yellow (Y), and black (K) sequentially perform imaging operations with magenta, yellow, and black after a predetermined period elapses from start of an imaging operation with cyan.

The sheet feed/transport unit 250 feeds a sheet from a sheet feed unit which is instructed in advance out of in-housing sheet feed units 252a and 252b, an external sheet feed unit 252c, and a bypass sheet feed unit 252d. A fed sheet is transported to a registration roller 254.

The registration roller 254 transports a sheet on the transfer belt 230 so that a toner image formed in the imaging unit 220 described above is transferred on the sheet.

An optical sensor 232 is arranged so as to face a face on which a toner image of the transfer belt 230 is transferred and performs position detection of a test chart printed on the transfer belt 230 in order to calculate a color displacement between development units. The color displacement calculated here is transmitted to an image controller unit (not illustrated) and used for correction of an image position of each color. This control enables a full-color toner image without color displacement to be transferred on a sheet.

The fixing unit 240 incorporates a plurality of rollers and a heat source such as a halogen heater, uses heat and pressure to dissolve and fix a toner on a sheet on which a toner image has been transferred from the transfer belt 230, and discharges the sheet out of the image forming apparatus 200 by using a sheet discharge roller 242.

The image forming control unit (not illustrated) is connected to a multifunction printer (MFP) control unit that controls the overall MFP including the image forming apparatus and performs control in accordance with an instruction from the MFP control unit. Further, the image forming control unit provides an instruction so that the entirety can maintain coordination to smoothly operate while managing the states of the scanner unit 210, the imaging unit 220, the fixing unit 240, and the sheet feed/transport unit 250 described above.

The exposure head 224 of the image forming apparatus according to the present embodiment will be described with reference to FIG. 16A and FIG. 16B. FIG. 16A illustrates the arrangement of the exposure head 224 relative to the photosensitive drum 222. FIG. 16B illustrates a view in which a light from the exposure head 224 is captured on the surface of the photosensitive drum 222.

As illustrated in FIG. 16A, the exposure head 224 is arranged so as to face the photosensitive drum 222. Each of the exposure head 224 and the photosensitive drum 222 is attached to the image forming apparatus 200 by an attachment member (not illustrated) for use.

As illustrated in FIG. 16B, the exposure head 224 has a surface light-emitting element array chip group 264, a printed circuit board 262 on which the surface light-emitting element array chip group 264 is implemented, and a rod lens array 266. Further, the exposure head 224 has a housing (support member) 260 that supports the rod lens array 266 and the printed circuit board 262.

The rod lens array 266 is an optical system that collects light from the surface light-emitting element array chip group 264. The exposure head 224 collects a light generated from a chip surface of the surface light-emitting element array chip group 264 onto the photosensitive drum 222 by the rod lens array 266 and forms an electrostatic latent image in accordance with image data on the photosensitive drum 222.

It is preferable that the exposure head 224 be configured to perform focus adjustment and light amount adjustment at each spot so that an assembly and adjustment operation is performed for a single exposure head in a factory and a light collecting position is located at an appropriate position when attached to an image forming apparatus. Herein, the components are arranged such that the distance between the photosensitive drum 222 and the rod lens array 266 and the distance between the rod lens array 266 and the surface light-emitting element array chip group 264 form predetermined gaps. Thereby, a light from the exposure head 224 is captured on the photosensitive drum 222. Thus, in focus adjustment, an attachment position of the rod lens array 266 is adjusted so that the distance between the rod lens array 266 and the surface light-emitting element array chip group 264 is a desired value. Further, in light amount adjustment, light-emitting points are sequentially caused to emit light, and the drive current at each light-emitting point is adjusted so that a light collected via the rod lens array 266 is a predetermined light amount.

The exposure head 224 of the present embodiment can be used preferably when exposure is performed on the photosensitive drum 222 to form an electrostatic latent image on the photosensitive drum 222. However, the use of the exposure head 224 is not particularly limited, and the exposure head 224 can also be used as a light source of a line scanner, for example.

The surface light-emitting element array chip group 264 of the image forming apparatus according to the present embodiment will be described with reference to FIG. 17A to FIG. 17C. FIG. 17A to FIG. 17C are diagrams schematically illustrating the printed circuit board 262 on which the surface light-emitting element array chip group 264 is arranged.

FIG. 17A schematically illustrates a face of the printed circuit board 262 on which the surface light-emitting element array chip group 264 is arranged, and the face is a face on which the surface light-emitting element array chip group 264 is mounted (hereinafter, referred to as “surface light-emitting element array mounting face”).

As illustrated in FIG. 17A, in the present embodiment, the surface light-emitting element array chip group 264 is formed of 29 surface light-emitting element array chips C1 to C29. The surface light-emitting element array chip group 264 is mounted on the surface light-emitting element array mounting face of the printed circuit board 262. The surface light-emitting element array chips C1 to C29 are arranged in two lines in a staggered manner on the printed circuit board 262. Each line of the surface light-emitting element array chips C1 to C29 is arranged along the longitudinal direction of the printed circuit board 262.

Each of the surface light-emitting element array chips C1 to C29 may be formed of the semiconductor light-emitting device 100 disclosed in any of the first to third embodiments. Each of the surface light-emitting element array chips C1 to C29 has 516 light-emitting points and 516 light-emitting thyristors L corresponding to respective light-emitting points. In each of the surface light-emitting element array chips C1 to C29, the 516 light-emitting thyristors L are aligned one-dimensionally at a predetermined pitch in the longitudinal direction of the chip. Adjacent light-emitting thyristors L are isolated by an element isolation groove. That is, the surface light-emitting element array chips C1 to C29 can be referred to as a light-emitting thyristor array in which a plurality of light-emitting thyristors L are aligned one-dimensionally. In the present embodiment, the pitch between adjacent light-emitting thyristors is 21.16 μm, which corresponds to the pitch of resolution of 1200 dpi. Further, the distance between both ends of the 516 light-emitting points in the chip is around 10.9 mm (≅21.16 μm×516).

FIG. 17B is a diagram schematically illustrating a face of the printed circuit board 262 on the opposite side of the surface light-emitting element array mounting face (hereinafter, referred to as “surface light-emitting element array non-mounting face”).

As illustrated in FIG. 17B, a drive unit 268a that drives the surface light-emitting element array chips C1 to C15 and a drive unit 268b that drives the surface light-emitting element array chips C16 to C29 are arranged on both sides of a connector 270 on the surface light-emitting element array non-mounting face. Signal lines that control the drive units 268a and 268b from an image controller unit (not illustrated), a power source, and a ground line are connected to the connector 270. Further, the drive units 268a and 268b on the surface light-emitting element array non-mounting face are connected to the connector 270 via wirings 272a and 272b, respectively. Wirings used for driving the surface light-emitting element array chips pass through an internal layer of the printed circuit board 262 from the drive units 268a and 268b and are connected to the surface light-emitting element array chips C1 to C15 and the surface light-emitting element array chips C16 to C29, respectively.

FIG. 17C illustrates a view of the boundary part between the surface light-emitting element array chip C28 and the surface light-emitting element array chip C29.

Wire bonding pads 280 and 290 used for inputting control signals are arranged at the ends of the surface light-emitting element array chips C28 and C29, respectively. Transfer units 282 and 292 of the surface light-emitting element array chips C28 and C29 and the light-emitting thyristors 284 and 294 are driven by signals input from the wire bonding pads 280 and 290, respectively. Also in the boundary part between the surface light-emitting element array chips, the pitch in the longitudinal direction of the light-emitting thyristors 284 and 294 is 21.16 μm corresponding to the pitch of resolution of 1200 dpi. Light-emitting thyristors of respective chips may be arranged to overlap each other taking mounting accuracy of chips into consideration.

Since the 29 surface light-emitting element array chips C1 to C29 having 516 light-emitting points per chip are aligned on the printed circuit board 262, the number of light-emitting thyristors L that can be caused to emit light is 14,964 in the overall surface light-emitting element array chip group 264. Further, the width where exposure is made by the surface light-emitting element array chip group 264 of the present embodiment is around 316 mm (≅10.9 mm×29). With a use of the exposure head on which the surface light-emitting element array chip group 264 is mounted, it is possible to form an image corresponding to such a width.

In the image forming apparatus of the present embodiment, since the number of components to be used is small, this facilitates reduction in size or reduction in cost of the apparatus compared to a laser scanning type image forming apparatus that polarizes and scans a laser beam by using a polygon motor.

### Modified Embodiments

The present invention is not limited to the embodiments described above, and various modifications are possible.

For example, an example in which a part of the configuration of any of the embodiments is added to another embodiment or an example in which a part of the configuration of any of the embodiments is replaced with a part of the configuration of another embodiment is also one of the embodiments of the present invention.

Further, although the transfer diode D and the gate resistor Rg are provided in the same mesa in the above embodiments, the transfer diode D and the gate resistor Rg may be provided in different mesas. Further, although the shift thyristor T and the light-emitting thyristor L are provided in different mesas in the above embodiments, the shift thyristor T and the light-emitting thyristor L may be provided in the same mesa.

Further, although one or four light-emitting thyristors L are connected to one shift thyristor T and one or four light-emitting thyristors L can simultaneously emit light in the above embodiment, the number of light-emitting thyristors L that can simultaneously emit light is not limited to one or four.

Further, although the shift thyristor T, the light-emitting thyristor L, and the parasitic thyristor P have been described with an example of n-gate type thyristors in the above embodiments, these thyristors may be formed of p-gate type thyristors. In such a case, the conductivity types of respective semiconductor layers forming the shift thyristor T, the light-emitting thyristor L, the parasitic thyristor P, and the transfer diode D are opposite.

Further, in the above embodiments, GaAs-based compound semiconductor materials containing at least Ga as a group III element and at least As as a group V element have been illustrated as an example for group III-V compound semiconductors forming the semiconductor light-emitting device. However, an InP-based compound semiconductor material containing at least In as a group III element and at least P as a group V element may be used as a group III-V compound semiconductors forming the semiconductor light-emitting device. Further, not only a group III-V compound semiconductor but also a group IV semiconductor or a group II-VI compound semiconductor may be used to form the semiconductor light-emitting device. Further, the composition, the thickness, the impurity concentration, or the like of a material forming the semiconductor layer described in the above embodiments are preferable examples and can be changed as appropriate.

Further, when the transfer diode portion, the shift thyristor portion, and the light-emitting thyristor portion are integrated on the same substrate, a distributed Bragg reflector layer (DBR layer) may be provided between the GaAs substrate 10A and the AlGaAs layer 12A in order to increase optical output of the light-emitting thyristor L. For example, the DBR layer can be configured to alternatingly stack AlGaAs layers of high Al composition and AlGaAs layers of low Al composition so that the optical length of each layer is λ/4. As a combination of the AlGaAs layer of the high Al composition and the AlGaAs layer of the low Al composition, Al_{0.8}Ga_{0.2}As and Al_{0.2}Ga_{0.8}G_{0.8}as or Al_{0.9}Ga_{0.1}As and Al_{0.1}Ga_{0.9}As can be applied, for example. With respect to the DBR layer, since a larger number thereof allows a higher reflectivity, it is preferable to form a stacked layers having around 20 layers or more.

Further, to increase light emission efficiency of the light-emitting thyristor L, the AlGaAs layer 16A or the AlGaAs layer 14A that is to be a light-emitting portion may be of the multi-quantum well (MQW) structure.

Further, the image forming apparatus illustrated in the above fourth embodiment is an example of an image forming apparatus to which the semiconductor light-emitting device of the present invention may be applied, and image forming apparatuses to which the semiconductor light-emitting device of the present invention is applicable are not limited to the configuration illustrated in FIG. 15. Further, the semiconductor light-emitting device of the present invention is applicable to various electronic apparatuses using a semiconductor light-emitting device without being limited to the image forming apparatus.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2019-070588, filed Apr. 2, 2019 which is hereby incorporated by reference herein in its entirety.

What is claimed is:

1. A semiconductor light-emitting device comprising: a shift thyristor; a light-emitting thyristor; and a transfer diode having one node connected to a gate of the shift thyristor and a gate of the light-emitting thyristor,
wherein the semiconductor light-emitting device includes a stacked structure including a first semiconductor layer of a first conductivity type provided over a semiconductor substrate, a second semiconductor layer of a second conductivity type, which is different from the first conductivity type, provided over the first semiconductor layer, a third semiconductor layer of the first conductivity type provided over the second semiconductor layer, and a fourth semiconductor layer of the second conductivity type provided over the third semiconductor layer,
wherein the stacked structure includes a first mesa and a second mesa,
wherein the transfer diode is provided in the first mesa,
wherein at least one of the shift thyristor and the light-emitting thyristor is provided in the second mesa,
wherein the semiconductor light-emitting device further includes a resistor connected to the other node of the transfer diode, and
wherein the resistor includes at least a part of the third semiconductor layer and includes a first electrode and a second electrode provided on the third semiconductor layer.

2. The semiconductor light-emitting device according to claim 1, wherein the transfer diode is formed of a p-n junction between the third semiconductor layer and the fourth semiconductor layer in the first mesa.

3. The semiconductor light-emitting device according to claim 2, wherein the transfer diode includes a third electrode provided on the fourth semiconductor layer.

4. The semiconductor light-emitting device according to claim 1,
wherein the first mesa further includes a fifth semiconductor layer of the first conductivity type provided over the fourth semiconductor layer, and
wherein the transfer diode is formed of a p-n junction between the fourth semiconductor layer and the fifth semiconductor layer in the first mesa.

5. The semiconductor light-emitting device according to claim 4, wherein the fourth semiconductor layer includes a first layer provided over the third semiconductor layer, a second layer provided over the first layer and having a higher impurity concentration than the first layer, and a third layer having a lower impurity concentration than the second layer.

6. The semiconductor light-emitting device according to claim 5, wherein the transfer diode includes a third electrode provided on the fifth semiconductor layer and a fourth electrode provided on the second layer.

7. The semiconductor light-emitting device according to claim 1,
wherein the stacked structure further includes a third mesa independent of the first mesa and the second mesa,
wherein the shift thyristor is provided in the second mesa, and
wherein the light-emitting thyristor is provided in the third mesa.

8. The semiconductor light-emitting device according to claim 7, wherein the stacked structure includes a plurality of first mesas corresponding to a plurality of transfer diodes, a plurality of second mesas corresponding to a plurality of shift thyristors, and a plurality of third mesas corresponding to a plurality of light-emitting thyristors.

9. An exposure head comprising:
the semiconductor light-emitting device according to claim 1; and
an optical system that collects a light from the semiconductor light-emitting device.

10. An image forming apparatus comprising:
an image carrier;
a charging unit that charges a surface of the image carrier;
an exposure head that includes the semiconductor light-emitting device according to claim 1 and exposes a surface of the image carrier charged by the charging unit to form an electrostatic latent image on the surface of the image carrier;
a development unit that develops the electrostatic latent image formed by the exposure head; and
a transfer unit that transfers an image developed by the development unit onto a recording medium.
